(19) United States
(12) Patent Application Publication
(10) Pub. No.: US 2011/0163432 A1
(43) Pub. Date: Jul. 7, 2011

(54) SEMICONDUCTOR DEVICE AND METHOD OF MANUFACTURING THE SAME

(75) Inventor: Chie Fujioka, Kyoto (JP)

(73) Assignee: PANASONIC CORPORATION, Osaka (JP)

(21) Appl. No.: 12/935,120

(22) PCT Filed: Nov. 26, 2009
(86) PCT No.: PCT/JP2009/006371

§ 371 Date: Sep. 28, 2010

(51) Int. Cl. H01L 23/495; H01L 21/58

(52) U.S. Cl. 257/676; 438/123; 257/E23.031; 257/E21.505

(57) ABSTRACT

Protrusions 310 are provided on the back side of a lead frame 301. During ultrasonic bonding, the lead frame 301 is placed on a stage and the protrusions 310 are brought into contact with or inserted into the stage, so that the lead frame 301 can be firmly retained on the stage.

### TECHNICAL FIELD

The present invention relates to a semiconductor device in which the electrode of a power semiconductor or the like and the electrode lead of a lead frame are connected via a conductive ribbon, and a method of manufacturing the same.

### BACKGROUND ART

There has been an increasing demand for higher power and a higher withstand voltage in power semiconductor devices in which power semiconductor elements such as a MOS-FET and an IGBT are mounted. Various semiconductor elements and packages for the semiconductor elements have been proposed in response to the demand.

In a semiconductor device and a method of manufacturing the same according to the prior art, a semiconductor element and an external terminal are bonded via a strip of Al (aluminum ribbon) to pass a large current with a low resistance, so that a resistance is reduced at the joints. In order to further reduce a resistance and improve connection stability, multiple Al ribbons are connected in a stacked manner with an increased cross sectional area.

FIG. 6 is a plan view showing the internal configuration of a semiconductor device according to the prior art. FIG. 6 shows a power semiconductor device, in which multiple aluminum ribbons are stacked, as the semiconductor device of the prior art.

In FIG. 6, a power semiconductor device 101 has a semiconductor element 103 mounted on a lead frame 102. On the surface of the semiconductor element 103, a source electrode 103a is formed. Provided on the source electrode 103a is a relatively thin conductive ribbon 105 bonded to the source electrode 103a by ultrasonic bonding. On the conductive ribbon 105, a conductive ribbon 106 is provided that is larger in thickness than the conductive ribbon 105. The conductive ribbon 106 is bonded by ultrasonic bonding with the conductive ribbon 105 interposed between the source electrode 103a and the conductive ribbon 106. The other side of the conductive ribbon 106 is similarly bonded to the lead frame 102 via a conductive ribbon 107 by ultrasonic bonding. Thus it is possible to reduce a resistance at the joints (e.g., see Patent Literature 1).

Referring to FIGS. 7(a) and 7(b), the following will describe a method of bonding an aluminum ribbon according to the prior art.

FIGS. 7(a) and 7(b) are explanatory drawings showing the method of bonding the aluminum ribbon in a method of manufacturing the semiconductor device according to the prior art.

The outer lead of the lead frame 102 is bent below a die pad, so that the lead frame 102 is hard to fix. Thus when the conductive ribbon 106 is bonded to the source electrode 103a or a source lead 104, the lead frame 102 is fixed by sucking the back side of the lead frame 102 by a sucking device 110 (FIG. 7(a)). Alternatively, the lead frame 102 is fixed by vertically clamping a region outside the bonded region of the lead frame 102 by a clamping device 111. In this state, ultrasonic waves are applied to the conductive ribbon 106 on the source electrode 103a or the source lead 104 from a bonding tool 112, so that the conductive ribbon 106 is bonded to the source electrode 103a or the source lead 104 (FIG. 7(b)). In another semiconductor device, a retaining region for a retainer is provided on the outer edge of a die pad (see Patent Literature 2).

### Citation List

### Patent Literature

Patent Literature 1: Japanese Patent Laid-Open No. 2008-117825
Patent Literature 2: Japanese Patent Laid-Open No. 10-303350

### SUMMARY OF THE INVENTION

### Technical Problem

However, in the method of fixing the lead frame during the ultrasonic bonding of the conductive ribbon to the electrode and so on according to the prior art, it is difficult to fix the lead frame with a sufficient strength during the ultrasonic bonding of the conductive ribbon. The lead frame resonating with ultrasonic vibrations may reduce stability and thus ultrasonic waves for bonding may not be sufficiently applied to the joint. In this case, disadvantageously, the bonding strength may become insufficient and reduce the reliability of bonding, so that a resistance may not be reduced. Further, in the case of bonding on the lead frame firmly fixed by a retainer or the like to suppress the resonance of the lead frame and improve the bonding reliability, retaining regions are provided on the die pad and the terminals of the lead frame, disadvantageously limiting the size of a semiconductor chip mounted on the die pad.

The present invention has been devised to solve the problems of the prior art. An object of the present invention is to more firmly bond a conductive ribbon by ultrasonic bonding and improve the reliability of bonding.

### Solution to Problem

In order to attain the object, a semiconductor device of the present invention includes: a semiconductor chip; a plurality of pads provided on the semiconductor chip; a lead frame including a die pad and a plurality of leads, the die pad including a mounting surface on which the semiconductor chip is mounted; a pad shaped portion formed on one ends of the leads; outer leads formed by bending the other ends of the leads to a non-mounting surface; a conductive ribbon electrically connecting the pad and the pad shaped portion; at least one first protrusion formed on the non-mounting surface of the die pad; at least one second protrusion formed on a surface provided in the same direction as the non-mounting surface of the pad shaped portion; and molding resin for molding the semiconductor chip, the conductive ribbon, the pad shaped portion, the first protrusion, and the second protrusion.

The semiconductor device preferably further includes at least one third protrusion formed on at least one of the non-mounting surface of the die pad and the surface provided in the same direction as the non-mounting surface of the pad shaped portion, wherein during ultrasonic bonding, the lead frame is fixed by fitting the third protrusion into one of a recessed portion and a through hole on a stage on which the lead frame is mounted.

A semiconductor device of the present invention includes: a semiconductor chip; a plurality of pads provided on the semiconductor chip; a lead frame including a die pad and a plurality of leads, the die pad including a mounting surface on which the semiconductor chip is mounted; a pad shaped portion formed on one ends of the leads; a conductive ribbon electrically connecting the pad and the pad shaped portion; at least one first protrusion formed on the non-mounting surface of the die pad; at least one second protrusion formed on a surface provided in the same direction as the non-mounting surface of the pad shaped portion; at least one third protrusion formed on at least one of the non-mounting surface of the die pad and the surface provided in the same direction as the non-mounting surface of the pad shaped portion; and molding resin for molding the semiconductor chip, the conductive ribbon, the pad shaped portion, the first protrusion, the second protrusion, and the third protrusion, wherein during ultrasonic bonding, the lead frame is fixed by fitting the third protrusion into one of a recessed portion and a through hole on a stage on which the lead frame is mounted.

At least one of the first protrusion and the second protrusion may be formed by bending the end of the lead frame.

Electric connection between the pad and the pad shaped portion may be partially made by one of a conductive wire and a bump.

Preferably, the first protrusion and the second protrusion have exposed ends from the molding resin.

A method of manufacturing a semiconductor device according to the present invention, when electrically connecting, via a conductive ribbon, a pad provided on a semiconductor chip and a pad shaped portion formed on leads, the method including: placing a lead frame on a stage, the lead frame including the leads and having the semiconductor chip mounted thereon; and connecting the conductive ribbon and one of the pad and the pad shaped portion by ultrasonic bonding in a state in which the lead frame is fixed on the stage, wherein the semiconductor device further includes a first protrusion on the non-mounting surface of the semiconductor chip, and a second protrusion on a surface provided in the same direction as the non-mounting surface of the pad shaped portion.

Preferably, the outer leads of the leads, the first protrusion, and the second protrusion are in contact with the stage.

Preferably, the semiconductor device further includes: a third protrusion on the non-mounting surface of the semiconductor chip; and one of a recessed portion and a through hole on the stage, the third protrusion being fit and retained into one of the recessed portion and the through hole.

Preferably, the semiconductor device further includes: a third protrusion on the non-mounting surface of the semiconductor chip; and one of a recessed portion and a through hole on the stage, the third protrusion being fit and retained into one of the recessed portion and the through hole, at least one of the first protrusion and the second protrusion being in contact with the side of the stage.

Electrical connection between the pad and the pad shaped portion may be partially made via one of a conductive wire and a bump.

Thus it is possible to more firmly bond the conductive ribbon by ultrasonic bonding, improve the reliability of bonding, and easily reduce a resistance at the joint.

### Advantageous Effects of Invention

As has been discussed, protrusions are provided on the back side of a lead frame and the lead frame is placed on a stage during ultrasonic bonding such that the protrusions are brought into contact with or inserted into the stage, so that the lead frame can be firmly retained on the stage.

### BRIEF DESCRIPTION OF DRAWINGS

FIG. 1(a) shows the configuration of a semiconductor device according to a first embodiment.

FIG. 1(b) shows the configuration of the semiconductor device according to the first embodiment.

FIG. 1(c) shows the configuration of the semiconductor device according to the first embodiment.

FIG. 2(a) is a perspective view showing the shape of a protrusion according to the first embodiment.

FIG. 2(b) is a perspective view showing the shape of the protrusion according to the first embodiment.

FIG. 3(a) is an explanatory drawing showing a method of manufacturing a semiconductor device according to a second embodiment.

FIG. 3(b) is an explanatory drawing showing the method of manufacturing the semiconductor device according to the second embodiment.

FIG. 3(c) is an explanatory drawing showing the method of manufacturing the semiconductor device according to the second embodiment.

FIG. 4 is an explanatory drawing showing a state of bonding of an aluminum ribbon according to the second embodiment.

FIG. 5(a) is an explanatory drawing showing the configuration of a semiconductor device according to a third embodiment.

FIG. 5(b) is an explanatory drawing showing the configuration of the semiconductor device according to the third embodiment.

FIG. 5(c) is an explanatory drawing showing the configuration of the semiconductor device according to the third embodiment.

FIG. 5(d) is an explanatory drawing showing the configuration of the semiconductor device according to the third embodiment.

FIG. 6 is a plan view showing the internal configuration of a semiconductor device according to the prior art.

FIG. 7(a) is an explanatory drawing showing a method of bonding an aluminum ribbon in a method of manufacturing the semiconductor device of the prior art.

FIG. 7(b) is an explanatory drawing showing the method of bonding the aluminum ribbon in the method of manufacturing the semiconductor device of the prior art.

### DESCRIPTION OF EMBODIMENTS

The following will describe embodiments of the present invention with reference to the accompanying drawings.

### First Embodiment

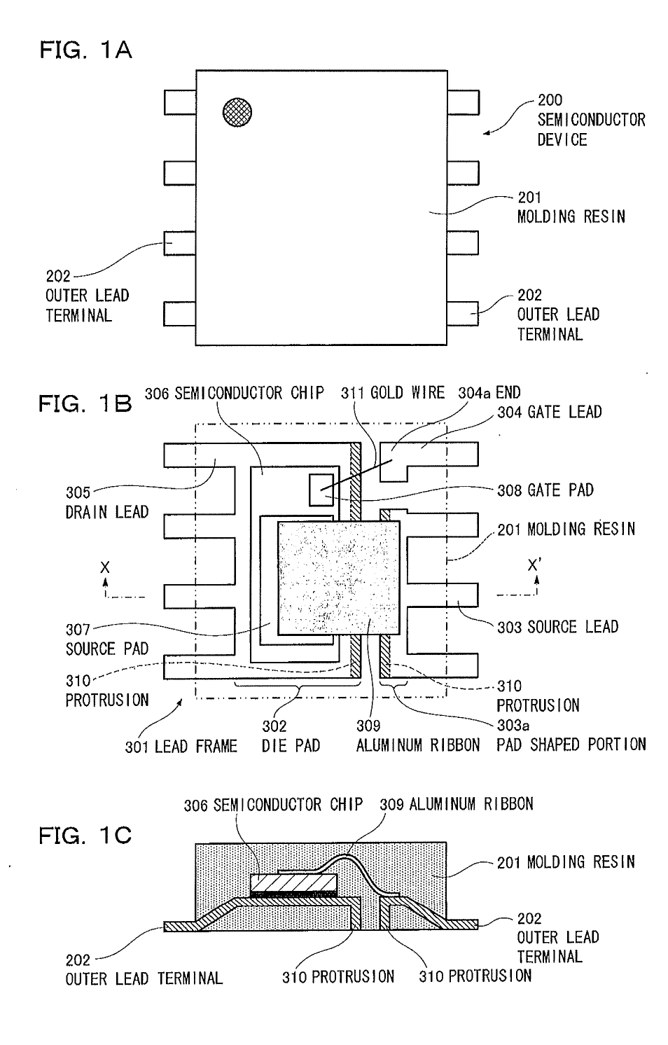

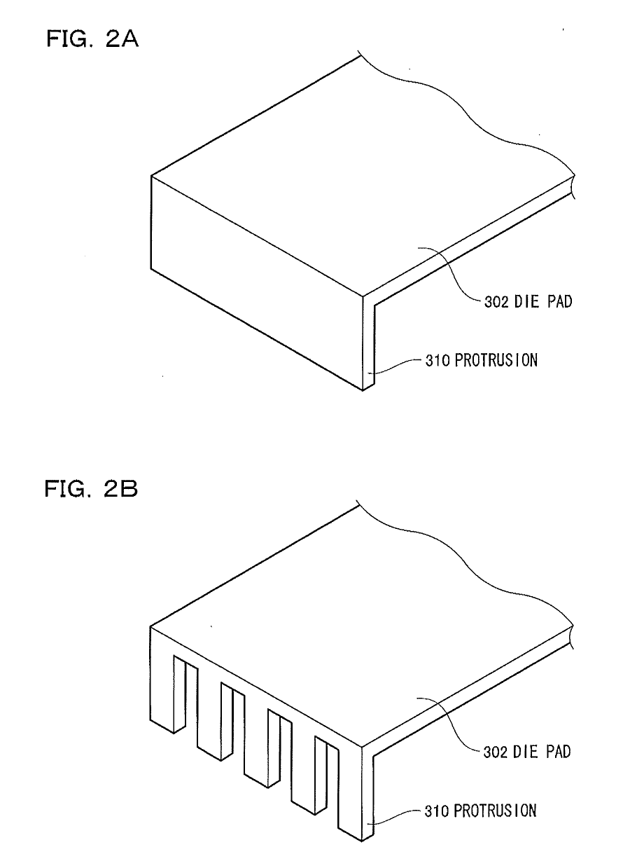

FIGS. 1(a) to 1(c) each show the configuration of a semiconductor device according to a first embodiment. FIG. 1(a) is an outside plan view of the semiconductor device including a semiconductor chip of a MOS-FET mounted in a package called SO8P. FIG. 1(b) is an internal structural diagram of FIG. 1(a). FIG. 1(c) is a sectional view taken along line X-X′ of FIG. 1(b). FIGS. 2(a) and 2(b) are perspective views showing the shape of a protrusion according to the first embodiment.

In FIGS. 1(a) to 1(c) and 2(a) and 2(b), a semiconductor device 200 of the present invention has outer lead terminals 202 protruding from molding resin 201. The semiconductor device 200 is connected to an external circuit and a substrate via the outer lead terminals 202.

A lead frame 301 is formed of a die pad 302, source leads 303, and a gate lead 304. The source leads 303 and the gate lead 304 are opposed to the die pad 302 in a separated manner. From the die pad 302, a plurality of leads are drawn as drain leads 305. The source lead 303 has a pad shaped portion 303a that is a combination of the multiple leads near the die pad.

The die pad 302, the pad shaped portion 303a of the source leads 303, and a die-pad side end 304a of the gate lead 304 are bent and are placed slightly higher than outer lead portions. The die pad 302, the pad shaped portion 303a of the source leads 303, and the die-pad side end 304a of the gate lead 304 may be flush with one another or the die pad 302 may be placed slightly lower.

The lead frame 301 is mainly made of copper (Cu) or a copper alloy. The die pad 302 is normally coated with silver (Ag) and the pad shaped portion 303a of the source leads 303 may be made of solid copper (Cu) without plating. The pad shaped portion 303a may be plated with silver (Ag) or nickel (Ni). The die-pad side end 304a of the gate lead 304 is normally plated with silver (Ag).

On the die pad 302, for example, a semiconductor chip 306 of a power MOS-FET is mounted and is bonded on the die pad 302 with a die bonding agent such as solder and silver (Ag) paste. The die bonding agent for bonding is not limited to solder and silver (Ag) paste as long as drain electrodes on the back side of the semiconductor chip 306 are electrically connected to the die pad 302.

On the semiconductor chip 306, a source pad 307 and a gate pad 308 are formed. The source pad 307 is connected to a source electrode and the gate pad 308 is connected to a gate electrode. The source pad 307 and the gate pad 308 are rectangular and the source pad 307 is larger than the gate pad 308. The gate pad 308 on the semiconductor chip 306 and the pad shaped portion 304a of the gate leads 304 are connected via a gold (Au) wire 311. The source pad 307 on the semiconductor chip 306 and the source leads 303 opposed to the source pad 307 are connected via an aluminum ribbon 309, and the aluminum ribbon 309 is bonded to the source pad 307 and the pad shaped portion 303a by ultrasonic bonding in a state in which the lead frame 301 is placed on a stage.

In order to suppress the resonance of the lead frame 301 during ultrasonic bonding in the semiconductor device of the first embodiment, protrusions 310 are formed on at least a part of the end of the non-mounting surface of the die pad 302 and at least a part of the end of the pad shaped portion 303a. The non-mounting surface is opposite from the semiconductor chip 306 mounted on the other surface of the die pad 302. The lead frame 301 is placed on the stage and the stage is brought into contact with the protrusions 310 and the outer leads to stably fix the lead frame 301 on the stage.

The protrusions 310 are formed by bending the end of the die pad 302 and the end of the pad shaped portion 303a of the source leads 303 to the non-mounting surface (FIG. 2(a)). The ends of the die pad 302 and the pad shaped portion 303a are opposed to each other in the lead frame 301. The protrusion 310 may be notched into multiple protrusions by etching or the like (FIG. 2(b)). Further, the opposed ends of the die pad 302 and the pad shaped portion 303a of the source leads 303 may be bent to the non-mounting surface in the lead frame 301, and both sides of the die pad may be bent. Although the protrusions 310 are formed by bending the ends of the lead frame 301, the protrusions 310 may be formed by bonding or the like in the same plane as a non-mounting surface between the bonded region of the die pad 302 and the source leads 303 and a non-mounting surface near the end of the pad shaped portion. The lead frame 301 is stabilized by retaining the protrusions 310 and the outer leads at two points on the stage. Preferably, the protrusions 310 are flush with the height of the bent outer lead, that is, a height from the mounting surface of the die pad 302 or the bonded surface of the pad shaped portion 303a to the underside that is the non-mounting surface of the outer lead, so that the bonded surface is placed in a horizontal position during ultrasonic bonding and the aluminum ribbon is more easily bonded.

The protrusions 310 are provided thus on the non-mounting surface of the lead frame 301, so that the lead frame 301 can be firmly retained and strong ultrasonic waves can be effectively transmitted to the lead frame 301 and the aluminum ribbon 309 during the ultrasonic bonding of the aluminum ribbon. For this reason, the aluminum ribbon 309 can be firmly fixed and a resistance can be easily reduced at the joint.

In ultrasonic bonding according to the prior art, the underside of the die pad 302 is sucked and the end of the lead frame 301 is fixed. Thus it is not possible to effectively transmit strong ultrasonic waves, resulting in insufficient fixation of the lead frame 301. Consequently, a bonding strength on the interfaces between the aluminum ribbon 309 and the source pad 307 and the source lead 303 may become insufficient or the aluminum ribbon 309 may be unbonded.

The aluminum ribbon 309 is bonded by ultrasonic bonding in a state in which the lead frame 301 is firmly fixed in contact with the stage by the die pad 302 and the pad shaped portion 303a of the source leads 303 with the protrusions 310 provided on the die pad 302 and the pad shaped portion 303a. Thus it is possible to firmly bond the aluminum ribbon 309 and improve the reliability of bonding, thereby easily reducing a resistance at the joint.

The provision of the protrusions 310 increases the bonded area of the lead frame 301 and the molding resin 201 and makes it possible to firmly fix the aluminum ribbon 309 without stacking the aluminum ribbons 309. Thus it is possible to easily reduce a resistance at the joint of the conductive ribbon while keeping the reliability of the semiconductor chip. As a matter of course, the resistance can be further reduced by stacking the aluminum ribbons 309.

Further, by exposing the ends of the protrusions 310 of the lead frame 301 from the molding resin, the protrusions 310 can act as heat dissipating parts that dissipate heat from the semiconductor device 200 to the outside.

The aluminum ribbon 309 is a strip of aluminum that can pass a large current with a low resistance. A strip of any conductive material may be used instead as long as the same effect can be obtained.

### Second Embodiment

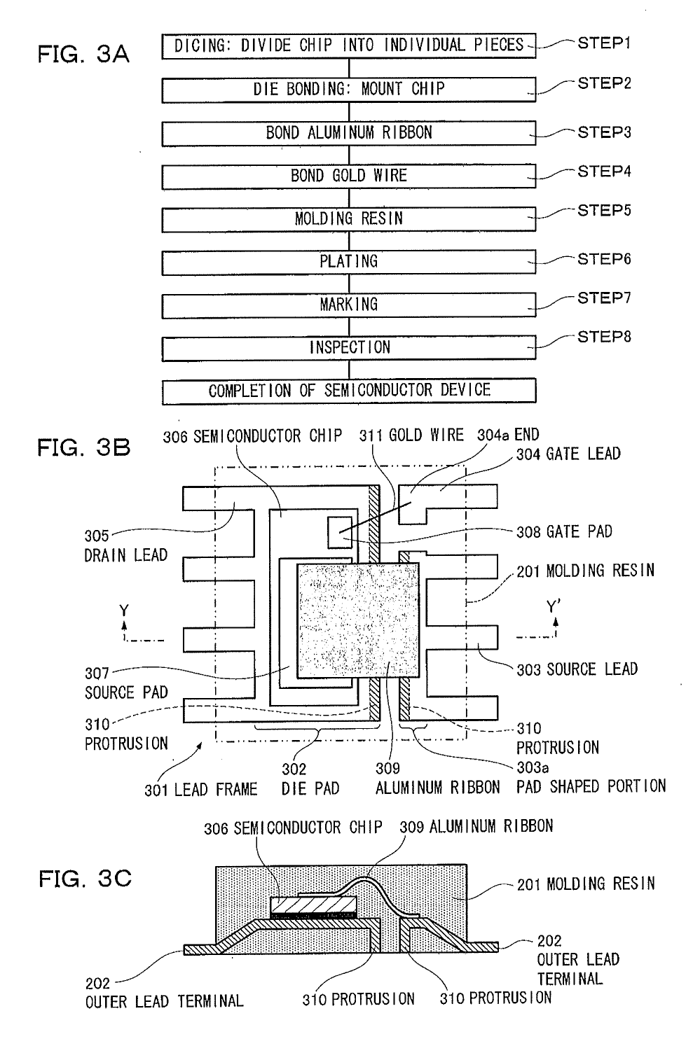

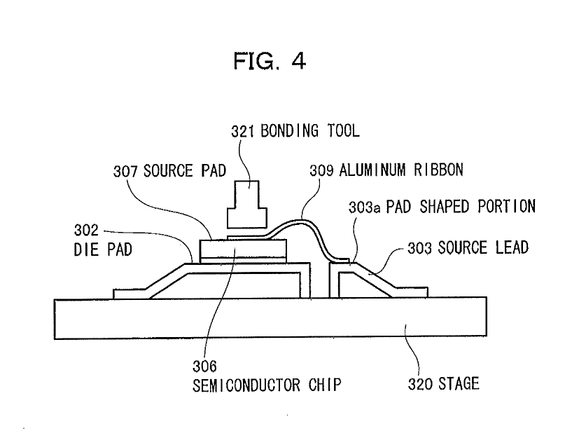

FIGS. 3(a) to 3(c) are explanatory drawings showing a method of manufacturing a semiconductor device according to a second embodiment. FIG. 3(a) is a process flowchart showing a method of manufacturing the semiconductor device of the present invention. FIG. 3(b) is a plan view for explaining the step of bonding a conductive ribbon in the process flowchart of FIG. 3(a). FIG. 3(c) is a sectional view taken along line Y-Y′ of FIG. 3(b). FIG. 4 is an explanatory drawing showing a state of a bonded aluminum ribbon according to the second embodiment.

In FIGS. 3(a) to 3(c) and 4, first, power MOS-FETs are formed on a silicon wafer and then the wafer is divided into pieces in a dicing step to fabricate semiconductor chips 306 (step 1).

Next, a die pad and leads are formed and then the semiconductor chip 306 is mounted on a die pad 302 of a lead frame 301, on which protrusions 310 are formed, with a die bonding agent such as silver (Ag) paste (step 2).

At this point, the protrusions 310 are formed as shown in FIGS. 2(a) and 2(b). The protrusions 310 are formed by bending protruded portions, which have been formed by etching or press working, by precision press working. Alternatively, the protrusions are formed by etching or combining etching and press working. At this point, during bending, it is preferable to perform bending with a die that forms slightly even surfaces on the protrusions, so that precise press working forms slightly uneven surfaces on the protrusions. During etching, the surface of the lead frame 301 and the protrusions 310 are preferably coated with a silane coupling agent or the like.

Next, the lead frame 301 on which the semiconductor chip 306 is mounted is set on a stage 320. At this point, the lead frame 301 is set such that the protrusions 310 are in contact with the stage 320. The lead frame 301 is firmly fixed on the stage 320 via the protrusions 310. After that, in this state, ultrasonic waves are applied from a bonding tool 321 to an aluminum ribbon 309, so that the aluminum ribbon is bonded (step 3). The aluminum ribbon 309 is placed on a source pad 307 on the semiconductor chip 306 and a pad shaped portion 303a that is a combination of source leads 303.

Next, a gate pad 308 on the semiconductor chip 306 and a gate lead 304 are connected via a gold (Au) wire 311 (step 4). The aluminum ribbon may be bonded before the gold wire and vice versa. It is desirable to bond the aluminum ribbon first because stronger ultrasonic waves are used in the bonding of the aluminum ribbon 309.

Next, the die pad 302, the semiconductor chip 306, the aluminum ribbon 309, the gold wire 311, inner lead portions, and the protrusions 310 are molded with molding resin 201 (step 5). At this point, it is desirable that the ends of the protrusions 310 are substantially flush with the undersides of outer lead terminals 202 and are exposed from the molding resin 201.

After that, a plating step (step 6) and a marking step (step 7) are performed, and then an inspecting step (step 8) is performed to check the quality of the semiconductor device, so that the semiconductor device is completed.

According to the semiconductor device manufactured by the manufacturing method, ultrasonic waves are used for bonding and thus the protrusions 310 can be fixed in contact with the stage. The protrusions 310 are formed at least on a part of the end of the non-mounting surface of the die pad 302. The non-mounting surface is opposite from the semiconductor chip 306 mounted on the other surface of the die pad 302.

Since the protrusions 310 are provided on the non-mounting surface of the lead frame 301, the lead frame 301 is firmly retained on the stage during the bonding of the aluminum ribbon and strong ultrasonic waves are effectively transmitted to the lead frame 301 and the aluminum ribbon 309, so that the aluminum ribbon can be firmly fixed. Thus it is possible to easily reduce a resistance at the joint of the conductive ribbon while keeping the reliability of the semiconductor chip. Further, it is possible to increase a bonding strength and reduce a resistance, eliminating the need for stacking aluminum ribbons.

When the protrusions are formed on the non-mounting surface of the lead frame 301 by bending or the like, slightly uneven surfaces are simultaneously formed on bended portions and contacted portions, thereby increasing a contact area with the molding resin 201. Consequently, adhesion is increased by an anchor effect with the molding resin 201. When the protrusions are formed on the non-mounting surface of the lead frame 301 by etching, the surface of the lead frame 301 is coated with the silane coupling agent. Thus it is possible to accelerate chemical bonding with the molding resin 201 and increase the adhesion.

Moreover, the ends of the protrusions 310 of the lead frame 301 are exposed from the molding resin 201, so that the protrusions 310 can act as heat dissipating parts that dissipate heat from a semiconductor device 200 to the outside. Thus it is possible to obtain a semiconductor device with high airtightness, heat dissipation, and bonding reliability.

### Third Embodiment

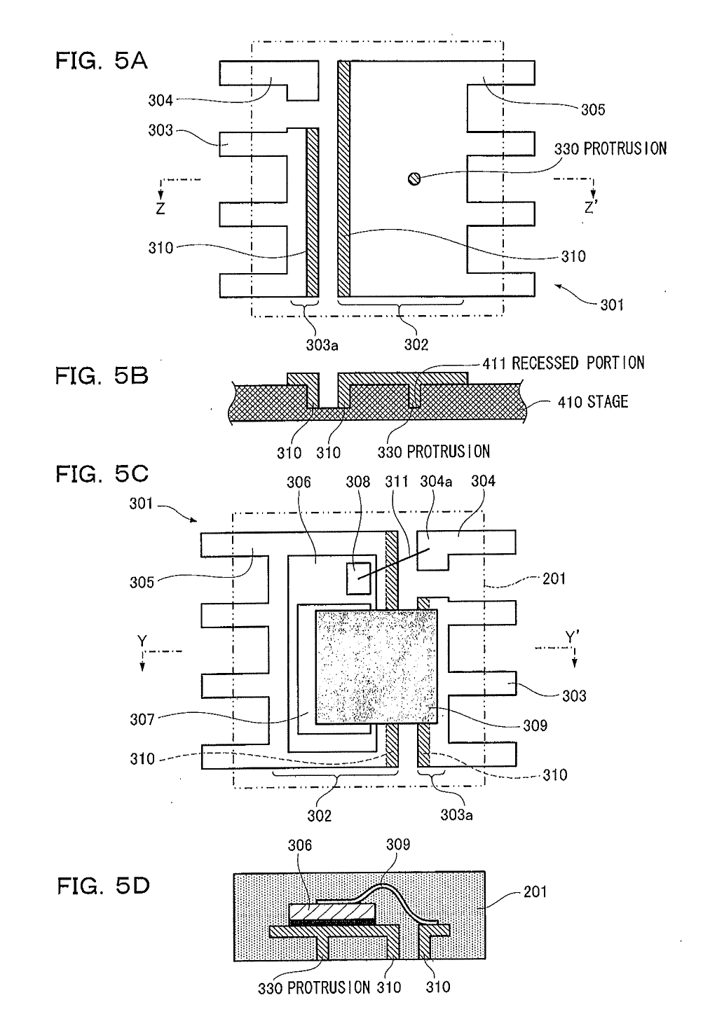

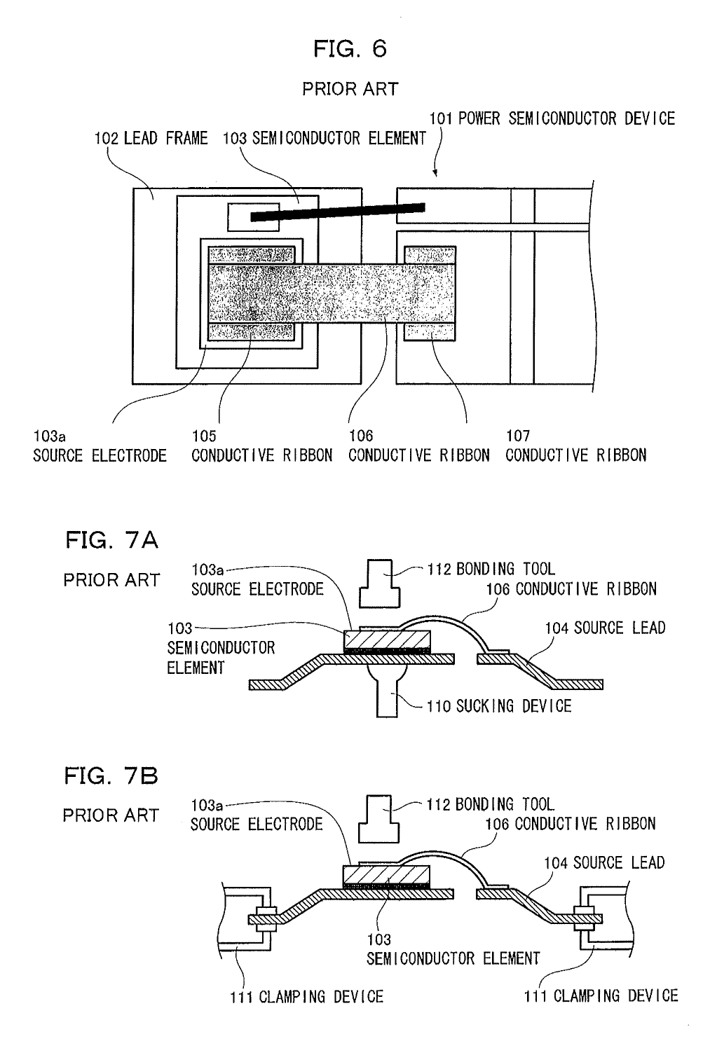

FIGS. 5(a) to 5(d) are explanatory drawings showing the configuration of a semiconductor device according to a third embodiment. FIG. 5(a) is a rear plan view for explaining protrusions provided on a lead frame. FIG. 5(b) shows the relationship between a cross section taken along line Z-Z′ of FIG. 5(a) and a stage. FIG. 5(c) is an internal structural diagram. FIG. 5(d) is a sectional view taken along line Y-Y′ of FIG. 5(c).

In FIGS. 5(a) to 5(d), the same constituent elements as those of FIGS. 3(a) to 3(c) are indicated by the same reference numerals and the explanation thereof is omitted.

In FIGS. 5(a) to 5(d), a protrusion 330 is provided on at least one of the non-mounting surface of a die pad 302 and the back side of a pad shaped portion, and a recessed portion 411 is provided on the mounting surface of a stage 410. The protrusion 330 is cylindrical or prismatic and the recessed portion 411 is shaped such that the protrusion 330 can be inserted and retained in the recessed portion 411.

The protrusion 330 shaped thus can be fit into the recessed portion 411 and firmly fixed in contact with the recessed portion 411. Further, protrusions 310 are provided that are shaped like the protrusions of the first and second embodiments. The stage 410 is formed such that the protrusions 310 come into contact with the side end faces of the stage 410 when a lead frame 301 is placed on the stage 410, so that the stage 410 is retained by the protrusions 310 and the protrusion 330. Thus it is possible to firmly fix the lead frame 301 on the stage 410. As in the first and second embodiments, the protrusion 330 may be inserted into the recessed portion 411 such that outer lead terminals 202 (see FIGS. 1(a) to 1(c)) and the protrusions 310 are in contact with the stage 410.

With this configuration, the protrusion 330 is provided on at least one of the non-mounting surface of the die pad 302 and the back side of the pad shaped portion and ultrasonic bonding is performed in a state in which the protrusion 330 is inserted and fixed into the recessed portion 411 on the mounting surface of the stage 410. Thus it is possible to effectively transmit strong ultrasonic waves, minimize the resonance of the lead frame 301, firmly bond an aluminum ribbon 309, and reduce a resistance at the joint.

In this case, a through hole may be provided instead of the recessed portion 411.

In the explanation of the foregoing embodiments, a power semiconductor device was described as a semiconductor device. The semiconductor device of the present invention is not limited to a power semiconductor device. The protrusions are provided partially on or over the leads and the die pad on which the terminal pads are electrically connected via the conductive ribbon such as an aluminum ribbon. Thus the present invention is applicable to various semiconductor devices. Further, the number of terminals is not limited and the connection types of the conductive ribbon, the conductive wire such as a gold wire, and bumps are optionally combined. Moreover, in the foregoing explanation, electric connection is made directly between the back side of the semiconductor chip and the die pad but it is not always necessary to connect the back side of the semiconductor chip.

### INDUSTRIAL APPLICABILITY

The present invention is useful for a semiconductor device and a method of manufacturing the same in which a conductive ribbon is firmly bonded by ultrasonic bonding, the reliability of bonding is improved, and the electrode of a power semiconductor or the like and the electrode lead of a lead frame are connected via the conductive ribbon.

1. A semiconductor device comprising:
a semiconductor chip;
a plurality of pads provided on the semiconductor chip;
a lead frame including a die pad and a plurality of leads, the die pad including a mounting surface on which the semiconductor chip is mounted;
a pad shaped portion formed on one ends of the leads;
outer leads formed by bending other ends of the leads to a non-mounting surface;
a conductive ribbon electrically connecting the pad and the pad shaped portion;
at least one first protrusion formed on the non-mounting surface of the die pad;
at least one second protrusion formed on a surface provided in a same direction as the non-mounting surface of the pad shaped portion; and
molding resin for molding the semiconductor chip, the conductive ribbon, the pad shaped portion, the first protrusion, and the second protrusion.

2. The semiconductor device according to claim 1, further comprising at least one third protrusion formed on at least one of the non-mounting surface of the die pad and the surface provided in the same direction as the non-mounting surface of the pad shaped portion,
wherein during ultrasonic bonding, the lead frame is fixed by fitting the third protrusion into one of a recessed portion and a through hole on a stage on which the lead frame is mounted.

3. A semiconductor device comprising:
a semiconductor chip;
a plurality of pads provided on the semiconductor chip;
a lead frame including a die pad and a plurality of leads, the die pad including a mounting surface on which the semiconductor chip is mounted;
a pad shaped portion formed on one ends of the leads;
a conductive ribbon electrically connecting the pad and the pad shaped portion;
at least one first protrusion formed on a non-mounting surface of the die pad;
at least one second protrusion formed on a surface provided in a same direction as the non-mounting surface of the pad shaped portion;
at least one third protrusion formed on at least one of the non-mounting surface of the die pad and the surface provided in the same direction as the non-mounting surface of the pad shaped portion; and
molding resin for molding the semiconductor chip, the conductive ribbon, the pad shaped portion, the first protrusion, the second protrusion, and the third protrusion,
wherein during ultrasonic bonding, the lead frame is fixed by fitting the third protrusion into one of a recessed portion and a through hole on a stage on which the lead frame is mounted.

4. The semiconductor device according to claim 1, wherein at least one of the first protrusion and the second protrusion is formed by bending an end of the lead frame.

5. The semiconductor device according to claim 2, wherein at least one of the first protrusion and the second protrusion is formed by bending an end of the lead frame.

6. The semiconductor device according to claim 1, wherein electric connection between the pad and the pad shaped portion is partially made by one of a conductive wire and a bump.

7. The semiconductor device according to claim 3, wherein electric connection between the pad and the pad shaped portion is partially made by one of a conductive wire and a bump.

8. The semiconductor device according to claim 1, wherein the first protrusion and the second protrusion have exposed ends from the molding resin.

9. The semiconductor device according to claim 3, wherein the first protrusion and the second protrusion have exposed ends from the molding resin.

10. A method of manufacturing a semiconductor device, when electrically connecting, via a conductive ribbon, a pad provided on a semiconductor chip and a pad shaped portion formed on leads, the method comprising:
placing a lead frame on a stage, the lead frame including the leads and having the semiconductor chip mounted thereon; and
connecting the conductive ribbon and one of the pad and the pad shaped portion by ultrasonic bonding in a state in which the lead frame is fixed on the stage,
wherein the semiconductor device further comprises a first protrusion on a non-mounting surface of the semiconductor chip, and a second protrusion on a surface provided in a same direction as the non-mounting surface of the pad shaped portion.

11. The method of manufacturing a semiconductor device according to claim 10, wherein outer leads of the leads, the first protrusion, and the second protrusion are in contact with the stage.

12. The method of manufacturing a semiconductor device according to claim 10, wherein the semiconductor device further comprises:
a third protrusion on the non-mounting surface of the semiconductor chip; and
one of a recessed portion and a through hole on the stage,
the third protrusion being fit and retained into one of the recessed portion and the through hole.

13. The method of manufacturing a semiconductor device according to claim 10, wherein the semiconductor device further comprises:
a third protrusion on the non-mounting surface of the semiconductor chip; and
one of a recessed portion and a through hole on the stage,
the third protrusion being fit and retained into one of the recessed portion and the through hole, at least one of the first protrusion and the second protrusion being in contact with a side of the stage.

14. The method of manufacturing a semiconductor device according to claim 10, wherein electrical connection between the pad and the pad shaped portion is partially made via one of a conductive wire and a bump.
